(19) United States
(12) Patent Application Publication
(10) Pub. No.: US 2014/0174362 A1
(43) Pub. Date: Jun. 26, 2014

(54) Apparatus And Methods For Symmetrical Gas Distribution With High Purge Efficiency

(71) Applicants: Chien-Teh Kao, Sunnyvale, CA (US); Mei Chang, Saratoga, CA (US); Hyman Lam, San Jose, CA (US); Joel M. Huston, San Jose, CA (US); Xiaoxiong Yuan, San Jose, CA (US); Olkan Cuvalci, Sunnyvale, CA (US)

(72) Inventors: Chien-Teh Kao, Sunnyvale, CA (US); Mei Chang, Saratoga, CA (US); Hyman Lam, San Jose, CA (US); Joel M. Huston, San Jose, CA (US); Xiaoxiong Yuan, San Jose, CA (US); Olkan Cuvalci, Sunnyvale, CA (US)

(21) Appl. No.: 14/133,813

(22) Filed: Dec. 19, 2013

Related U.S. Application Data
(60) Provisional application No. 61/745,093, filed on Dec. 21, 2012.

(51) Int. Cl. C23C 16/455; C23C 16/50

(52) U.S. Cl. CPC C23C 16/45565; C23C 16/50
USPC 118/723 R; 239/565

(57) ABSTRACT

Provided are apparatus and methods for depositing materials by vapor deposition and plasma enhanced vapor deposition techniques, and more particularly a gas distribution assembly and vapor deposition chamber to deposit a material. The gas distribution assembly comprises a plurality of sections with each section containing a flow channel with passages extending from the flow channel to the processing region of a processing chamber.

### CROSS-REFERENCE TO RELATED APPLICATIONS

This application claims priority to U.S. Provisional Application No. 61/745,093, filed Dec. 21, 2012.

### FIELD

Embodiments of the invention generally relate to an apparatus and a method for depositing materials. More specifically, embodiments of the invention relate to gas distribution plates, and more particularly to vapor deposition chambers incorporating the gas distribution plates, that provide symmetrical gas delivery.

### BACKGROUND

In the field of semiconductor processing, flat-panel display processing or other electronic device processing, vapor deposition processes have played an important role in depositing materials on substrates. As the geometries of electronic devices continue to shrink and the density of devices continues to increase, the size and aspect ratio of the features are becoming more aggressive, e.g., feature sizes of 0.07 μm and aspect ratios of 10 or greater. Accordingly, conformal deposition of materials to form these devices is becoming increasingly important.

While conventional chemical vapor deposition (CVD) has proved successful for device geometries and aspect ratios down to 0.15 μm, the more aggressive device geometries require an alternative deposition technique. One technique that is receiving considerable attention is atomic layer deposition (ALD). During an ALD process, reactant gases are sequentially introduced into a deposition chamber containing a substrate. Generally, a first reactant is pulsed into the deposition chamber and is adsorbed onto the substrate surface. A second reactant is pulsed into the deposition chamber and reacts with the first reactant to form a deposited material. A purge process is typically carried out between the delivery of each reactant gas. The purge process may be a continuous purge with the carrier gas or a pulse purge between the delivery of the reactant gases. Thermally induced ALD processes are the most common ALD technique and use heat to cause the chemical reaction between the two reactants. While thermal ALD processes work well to deposit some materials, the processes often have a slow deposition rate. Therefore, fabrication throughput may be impacted to an unacceptable level. The deposition rate may be increased at a higher deposition temperature, but many chemical precursors, especially metal-organic compounds, decompose at elevated temperatures.

Plasma-enhanced CVD (PE-CVD) and plasma-enhanced ALD (PE-ALD) may be used to form various materials. In some examples of PE-ALD processes, a material may be formed from the same chemical precursors as a thermal ALD process, but at a higher deposition rate and a lower temperature. Although several variations of techniques exist, in general, a PE-ALD process provides that reactant gas and reactant plasma are sequentially introduced into a deposition chamber containing a substrate. The first reactant gas is pulsed into the deposition chamber and is adsorbed onto the substrate surface. Thereafter, the reactant plasma generally supplied by a plasma source is pulsed into the deposition chamber and reacts with the first reactant gas to form a deposited material. Similarly to a thermal ALD process, a purge process may be conducted between the delivery of each of the reactants.

There is an ongoing need in the art for an apparatus capable of delivering and a process for depositing a material on a substrate by a vapor deposition technique, such as by a PE-ALD process.

### SUMMARY

Embodiments of the invention are directed to gas distribution assemblies comprising a showerhead comprising a body with a first surface and a second surface. The showerhead is divided into a plurality of sections. Each of the plurality of sections comprises a flow channel extending through the body of the showerhead. The flow channel includes an inlet end and an outlet end. The inlet end is in fluid communication with an inlet and the outlet end is in fluid communication with an outlet. A plurality of passages extend from the flow channel through the body to the first surface to form an aperture on the first surface so that a gas in the flow channel can flow through the passages and out of the apertures on the first surface.

In some embodiments, each section is about one-quarter of the showerhead. In one or more embodiment, the flow channel in each section comprises a series of connected L-shaped portions decreasing in size from a center of the showerhead toward an outer portion of the showerhead. In some embodiments, the flow channels in each section are rotationally symmetrical to the other flow channels and each flow channel is in flow communication with a separate inlet and outlet. In one or more embodiments, the flow channel in each section are mirror images of the adjacent sections and two adjacent sections share one of the inlet and outlet and have separate of the other of the inlet and outlet.

In some embodiments, the flow channel in each section comprises a first leg extending from a first corner of the section from one of the inlet and outlet toward a center of the showerhead where the flow channel turns to a second leg extending from the center toward a second corner of the section and transitioning to a series of switchback paths extending along a length of the second leg between the first leg and an edge of the section to the other of the inlet and outlet. In one or more embodiments, the flow channels in each section are rotationally symmetrical to the other flow channels and each flow channel is in fluid communication with a separate inlet and outlet. In some embodiments, the flow channel in each section is a mirror image of the adjacent sections and two adjacent section share on of the inlet and out and a separate of the other of the inlet and outlet.

In some embodiments, the showerhead is divided into two equal sections. In one or more embodiments, the flow channel in each section comprises a first leg extending from an edge of the section across the diameter of the showerhead toward about the opposite edge of the section transitioning to a series of switchback paths extending along the length of the first leg with increasing distance from the first leg.

In some embodiments, the showerhead is divided into eight equal sections.

One or more embodiments further comprises an electrode to be coupled with an RF power source to generate a plasma in the flow channel.

In some embodiments, each of the plurality of sections comprises an upper flow channel and a lower flow channel, the upper flow channel in flow communication with a first gas and the lower flow channel in flow communication with a second gas different from the first gas, a plurality of passages connects the upper flow channel to the first surface and a plurality of passages connects the lower flow channel to the first surface. In one or more embodiments, the upper flow channel comprises a wall and a plenum above the inlet, the wall including a plurality of openings to allow a gas to flow from the inlet into the plenum and the plurality of passages connecting the upper flow channel to the first surface are in fluid communication with the plenum. In some embodiments, the upper flow channel further comprises an electrode connected to an RF power source to generate a plasma in the plenum. In one or more embodiments, the plurality of passages connecting the upper flow channel to the first surface are funnel shaped with a wider opening in the plenum than at the first surface. In some embodiments, each of the plurality of passages independently includes an angled portion in a middle of the passageway to offset of the passageway to direct a flow of gas perpendicular to the first surface so that from the first surface, the plurality of passageways form a checkerboard pattern with alternate passageways in communication with different channels.

Additional embodiments of the invention are directed to chambers for plasma enhanced processing of one or more substrates. The chambers comprise a chamber body defining a process volume and a substrate support in the process volume to support one or more substrates. A showerhead comprises a body with a first surface and a second surface. The showerhead is divided into a plurality of sections, each of the plurality of sections comprising a flow channel extending through the body of the showerhead, the flow channel including an inlet end and an outlet end. The inlet end is in fluid communication with an inlet and the outlet end is in fluid communication with an outlet. A plurality of passages extend from the flow channel through the body to the first surface to form an aperture on the first surface so that a gas in the flow channel can flow through the passages and out of the apertures on the first surface. A plasma forming gas source is coupled with the showerhead. A reactant gas source is coupled with the showerhead.

In some embodiments, each of the plurality of sections comprises an upper flow channel and a lower flow channel, the upper flow channel in flow communication with a first gas and the lower flow channel in flow communication with a second gas different from the first gas, a plurality of passages connects the upper flow channel to the first surface and a plurality of passages connects the lower flow channel to the first surface.

Further embodiments of the invention are directed to gas distribution assemblies comprising a showerhead. The showerhead comprises a body with a first surface and a second surface and is divided into a plurality of sections. Each of the plurality of sections comprises an upper flow channel extending through the body of the showerhead and a lower flow channel extending through the body of the showerhead. Each flow channel includes an inlet end and an outlet end, the inlet end is in fluid communication with an inlet and the outlet end is in fluid communication with an outlet. A plurality of passages extend from the upper flow channel through the body to the first surface to form an aperture on the first surface so that a gas in the upper flow channel can flow through the passages and out of the apertures on the first surface. At least some of the passageways include an angled portion to offset the flow of gas through the passageway. A plurality of passages extend from the lower flow channel through the body to the first surface to form an aperture on the first surface so that a gas in the lower flow channel can flow through the passages and out of the apertures on the first surface. At least some of the passageways include an angled portion to offset the flow of gas through the passageway.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a showerhead assembly with multiple inlets in accordance with one or more embodiment of the invention;

FIG. 2 shows a showerhead assembly with multiple inlets and outlets in accordance with one or more embodiment of the invention;

FIG. 3A a partial showerhead assembly in accordance with one or more embodiment of the invention;

FIG. 3B shows an expanded view of a portion of the showerhead assembly of FIG. 3A;

FIG. 4 shows a showerhead assembly in accordance with the embodiment of FIG. 3A with multiple inlets and outlets;

FIG. 5 shows another showerhead assembly in accordance with the embodiment of FIG. 3A with multiple inlets and outlets;

FIG. 6A shows a partial showerhead assembly in accordance with one or more embodiment of the invention;

FIG. 6B shows an expanded view of a portion of the showerhead assembly of FIG. 6A;

FIG. 7 shows a showerhead assembly in accordance with the embodiment of FIG. 6A with multiple inlets and outlets;

FIG. 8 shows another showerhead assembly in accordance with the embodiment of FIG. 6A with multiple inlets and outlets;

FIG. 9 shows a partial showerhead assembly in accordance with one or more embodiment of the invention;

FIG. 10 shows a showerhead assembly in accordance with the embodiment of FIG. 9 with multiple inlets and outlets;

FIG. 11A shows a partial showerhead assembly in accordance with one or more embodiment of the invention;

FIG. 11B shows an expanded view of a portion of the showerhead assembly of FIG. 11A;

FIG. 12 shows a showerhead assembly in accordance with the embodiment of FIG. 11 A with multiple inlets and outlets;

FIG. 13 shows a cross-sectional view of a showerhead in accordance with one or more embodiment of the invention;

FIG. 14 shows a cross-sectional view of a showerhead in accordance with one or more embodiment of the invention;

FIG. 15 shows a cross-sectional view of a showerhead in accordance with one or more embodiment of the invention;

FIG. 16A a cross-sectional view of a portion of a showerhead in accordance with one or more embodiment of the invention;

FIG. 16B shows a view of the face of the showerhead in accordance with FIG. 16A;

FIG. 16C shows a view of the face of the showerhead in accordance with FIG. 5;

FIG. 17 is a schematic view of a process chamber with a process lid assembly in accordance with one or more embodiment of the invention;

FIG. 18 is a schematic view of a process chamber with a process lid assembly in accordance with one or more embodiment of the invention;

FIG. 19 is a partial cross-sectional view of an electrode for a process lid assembly in accordance with one or more embodiment of the invention; and

FIG. 20 is a partial cross-sectional view of a showerhead assembly for a process lid assembly in accordance with one embodiment of the invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the invention provide chemical (process gases or precursors) flow channel patterns that have (1) symmetrical gas distribution to deliver chemicals over a large wafer area for uniform film deposition, and (2) high purge efficiency to remove reactive chemicals from the flow channel for effective sequential CVD and ALD processes.

The flow channel patterns of various embodiments may be manufactured in the following manner: (1) A circular plate is divided into pie sections with an equal area, each of which is defined by two straight edges connecting at the center of the plate with a section of the circumference as the third boundary; (2) In each pie section, there are a series of straight gas flow channel pairs cut in parallel to each other with an equal space of uncut material between any two adjacent channel pairs. Of each pair of the channels, one channel is cut in parallel to one of the straight edge of the pie section from the circumference edge toward the tip of the pie section, while the other channel is cut in the same fashion parallel to the other straight edge. The two corresponding channels are connected at the shared end near the tip of the pie section; (3) Along the circumference edge of each pie section, there are a series of short channels alternately connecting the above-mentioned channel pairs to form a single flow channel within the pie section. The complete flow channel has two channel openings along the circumference. One of the openings is at the end of a channel section parallel and next to the straight edge, while the other one is near the center of the circumference edge; (4) Accompanied with another plate with a flat surface on top of the above-mentioned machined plate, a sandwiched distribution plate assembly is formed with embedded flow paths (one in each pie section) allowing chemicals to flow across the entire plate area; (5) To allow a group of compatible process gases flowing through the gas channels to be distributed for wafer processing, a set of through-holes are drilled along the base of the channels on one of the plates for chemicals to enter the process cavity on the other side of the plate and reach the wafer surface in the process chamber; and (6) For a second group of compatible process gases, but incompatible with the first gas group, to be distributed for wafer processing, another set of through-holes is drilled through the entire distribution plate (hence, both individual plates) along the walls of the complete channels, which is the uncut space of the machined plate between the adjacent individual channels.

The number of pie sections to form gas flow paths can be any number with an equal area for all sections. Examples of 2-, 4-, 8-section versions are shown in the Figures, but it will be understood by those skilled in the art that these are merely exemplary embodiments and that other embodiments are possible. Other symmetrical flow patterns, which are fabricated in a slightly different fashion from the above description, are also within the scope of the invention.

In addition, embodiments of the invention include arrangements to use the above-mentioned gas flow plate assembly, accompanied with other components, such as a plasma source. Some embodiments are directed to symmetrical flow channel assemblies with top precursor gas inputs. Assemblies may comprise a distribution plate with a single set of embedded gas channels having one of the symmetrical chemical flow patterns mentioned above, along with a set of through-holes. A pass-through space is formed by an electrically grounded enclosure plate (with gas inputs) placed on top of the dual-channel distribution plate. One or more compatible gases is distributed through the set of embedded gas channels to the wafer surface for processing. A second group of compatible gases, but incompatible with the first gas may by distributed across the pass-through space on top of the distribution plate. This group of compatible gases is delivered to the wafer surface for processing separately via the through-holes on the distribution plate and mixed with the first gas group right above the wafer surface in the process cavity.

Some embodiments are directed to symmetrical flow channel assemblies with dual channel gas inputs/outputs. These assemblies comprise a dual-channel distribution plate with two independent sets of embedded gas channels having one (or more) of the symmetrical gas flow patterns described, along with a set of through-holes. A pass-through space is formed by an electrically grounded enclosure plate (with no gas inputs) placed on top of the dual-channel distribution plate. One group of compatible gases is distributed through the bottom set of the embedded gas channels to the wafer surface for processing. A second group of compatible gases, but incompatible with the first gas group, is distributed through the top set of the embedded gas channels to the pass-through space on top of the dual-channel distribution plate and then via the through-holes on the distribution plate to the wafer surface for processing.

One or more embodiments of the invention are directed to symmetrical flow channel assemblies with dual channel gas inputs/output and plasma source. These assemblies is similar to those described above and comprise a dual-channel distribution plate with two independent sets of embedded gas channels having one (or more) of the symmetrical gas flow patterns mentioned above, along with a set of through-holes. An RF electrode is in place of the electrically grounded enclosure place, separated a ring of a selected dielectric material, to define a plasma cavity, which also serves as a pass-through space to distribute the radicals generated by plasma excitation. One group of compatible gases is distributed through the bottom set of the embedded gas channels to the wafer surface for processing. A second group of compatible gases, but incompatible with the first gas group, is distributed through the top set of the embedded gas channels to the plasma cavity on top of the dual-channel distribution plate and excited by the plasma there to generate reactive radicals. The radicals are then delivered via the through-holes on the distribution plate to the wafer surface for processing.

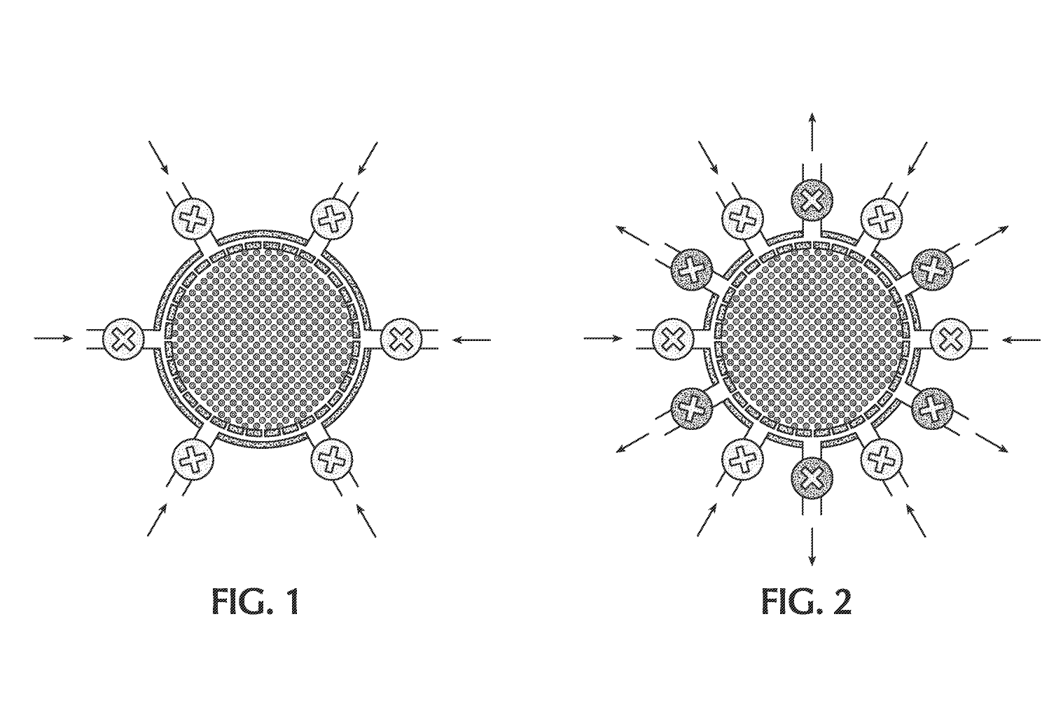

The symmetrical gas flow patterns and assemblies according to one or more embodiments may provide one or more of (1) efficient and complete removal of reaction gases compared to the open flow patterns, shown in FIG. 1 in the attached file with gas inputs only and FIG. 2 with both gas inputs and outputs. The flow patterns of various embodiments provide complete reaction gases removal from the entire gas distribution system due to minimal or no dead space in the designs, with high removal efficiency by purge owing to streamline design of the flow channels; (2) Uniform distribution and mixing of incompatible gases because of the symmetrical arrangements of flow channels, distribution holes in the independent flow channels for incompatible gas groups enables uniform distribution and mixing of these gas groups delivered through these independent flow channels; (3) Straightforward machining and lower fabrication cost. With the open flow patterns, shown in FIGS. 1 and 2, standing bosses defining the flow paths are machined in the distribution plate assembly that is time-consuming and costly to fabricate. In comparison, the proposed flow patterns can be machined with straight cuts that are straightforward and considerably cheaper.

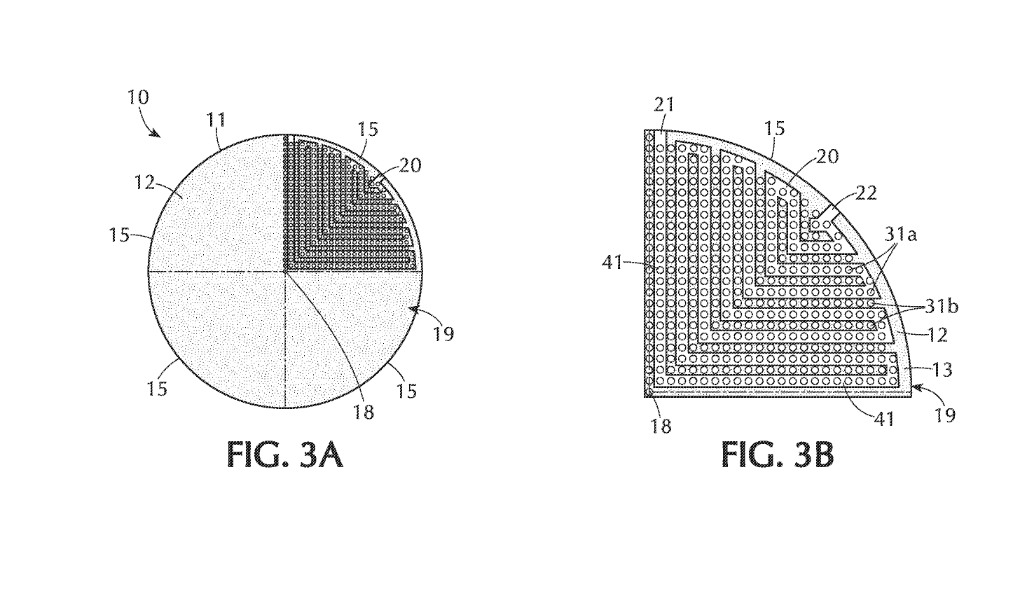

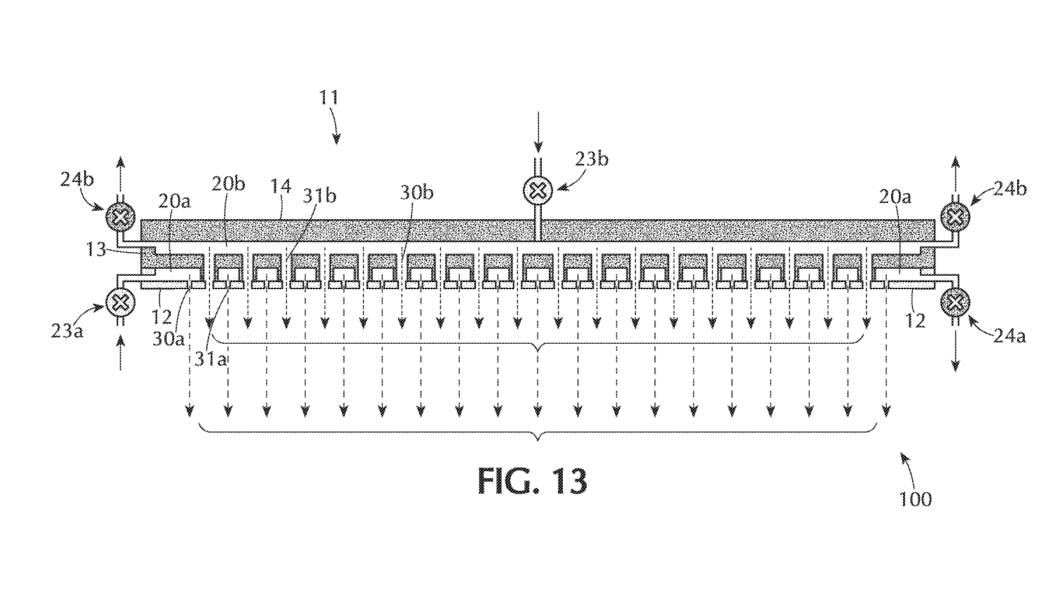

Accordingly, embodiments of the invention are directed to gas distribution assemblies and processing chambers incorporating same. FIG. 3A shows the first surface 12 of a showerhead 11, a part of the gas distribution assembly 10, in accordance with one or more embodiment of the invention. As can be seen in FIG. 13, the showerhead 11 comprises a body 13 with a first surface 12 and a second surface 14.

Referring again to FIG. 3A, the showerhead 11 is divided into a plurality of sections 15. FIG. 3A shows a showerhead 11 divided into four sections, each taking about one-fourth of the showerhead 11. This is merely exemplary, and as shown in other embodiments, the showerhead 11 can be divided into any number of sections having about equal area. Each of the four sections shown in FIG. 3B has about equal areas. As used in this specification and the appended claims, the term “equal area”, and the like, mean that each of the areas of the first surface attributed to the sections are within about 5% of each other.

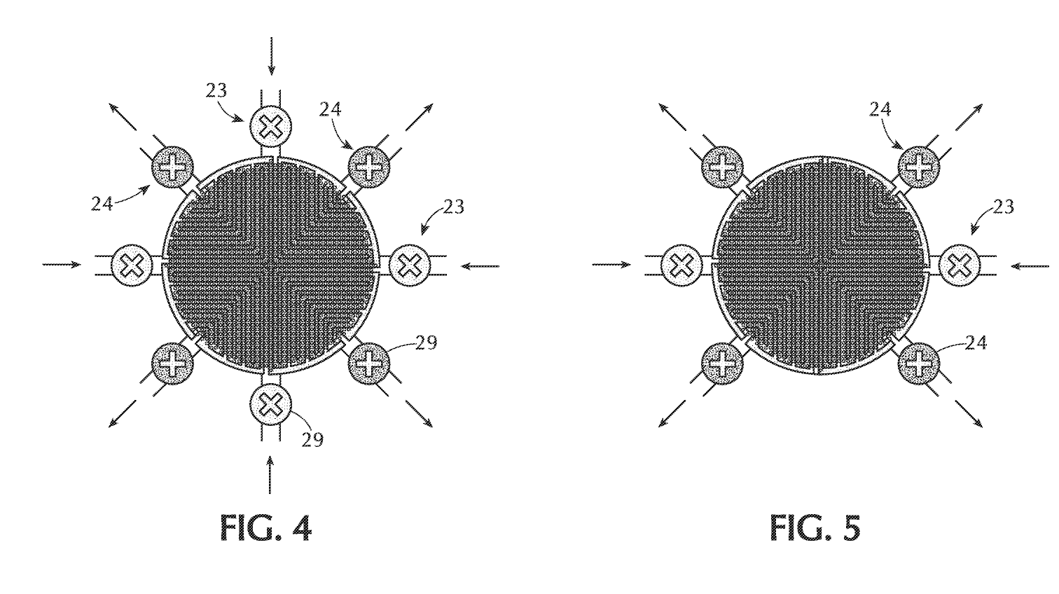

Each of the plurality of sections 15 comprises a flow channel 20. FIG. 3A only shows one flow channel 20 in the upper right section. However, it will be understood that this is merely for illustrative purposes and that flow channels 20 will be located in each of the sections 15. FIG. 3B shows an expanded view of the flow channel 20 shown in FIG. 3A. The flow channels 20 extend through the body 13 of the showerhead 11. The flow channel 20 includes an inlet end 21 and an outlet end 22. The inlet end 21 is in fluid communication with an inlet 23 (see FIG. 4) and the outlet end 22 is in fluid communication with an outlet 24 (see FIG. 4). The inlet end 21 and outlet end 22 marked on FIG. 3B are illustrative only and can be reversed.

A plurality of passages 30 extend from the flow channel 20 through the body 13 of the showerhead 11 to the first surface 12 to form an aperture 31 on the first surface 12 so that a gas in the flow channel 20 can flow through the passages 30 and out of the apertures 31 on the first surface 12. Again, this can be seen in the side view of the showerhead shown in FIG. 13.

In some embodiments, each section 15 of the showerhead 11 is about one-quarter of the showerhead. This can also be referred to as occupying about one-quarter of the area of the first surface.

Many factors can affect the flow of gas through the flow channel 20. For example, the shape of the channel including the number and angle of turns. Without being bound by any particular theory of operation, it is believed that the more bends there are in the channel, the greater the pressure drop across the channel (lengthwise) will be. This is believed to be true for the angle of the turns as well.

In one or more embodiments, the flow channel 20 in each section comprises a series of connected L-shaped portions. This can be seen in the embodiment of FIG. 3B. Each of the L-shaped portions shown in FIG. 3B have about equal length legs 41 for each equivalent row. For example, the channel row closes to the center of the showerhead has about equal length legs. Although it will be understood by those skilled in the art that there will be variability in the length of the legs and that this should not be taken as limiting the scope of the invention. For example, the left-most leg 41 shown is slightly longer than the bottom-most leg because the left-most leg connects to the inlet 21. The size of the L-shaped portions decreases as each portion moves further from the center 18 of the showerhead 11 toward an outer portion 19 of the showerhead.

In some embodiments, the flow channels in each section are rotationally symmetrical to the other flow channels. As used in this specification and the appended claims, the term “rotationally symmetrical” means that when looking at the first surface, turning the showerhead by 1/nth will result in an identical appearing gas distribution assembly 10, where n is the number of sections 15. For example, the embodiment shown in FIG. 4 is rotationally symmetrical because a one-quarter rotation of the page would result in an identical appearing assembly. By “identical appearing” it is meant that, as shown in the Figures, the shape of the channel 20 and positions of the inlet 23 and outlet 24 are the same.

It can be seen from FIG. 4, that each section 15 is in flow communication with a separate inlet 23 and outlet 24 from the other sections 15. The various inlets 23 and outlets 24 may have a common source of pump, but the connection to the showerhead 11 is through different lines. Each of the inlet 23 and outlet 24, independently, can include a metering device 29 (e.g., a valve) to control the flow of gases through the inlet and outlet. These metering devices 29 can be connected to a computer or feedback circuit which can automatically open or close based on the processing requirements.

In some embodiments, as shown in FIG. 5, the flow channel 20 in each section 15 are mirror images of the adjacent sections 15. As used in this specification and the appended claims, the term “mirror images” means that if a first section were flipped about one radial axis to form a second section, the flow channel design of the first section would form a mirror image of the second section. This does not meant that the direction of the passages and the first surface change, it merely refers to the design, or shape, of the flow channel and the location of the inlet and outlet. For example, FIG. 5 shows an embodiment where the sections are mirror images.

It can also be seen from FIG. 5, that two adjacent sections 15 share a single inlet 23 and each has a separate outlet 24. This is merely illustrative of one possible embodiment and these can be reversed. For example, the inlet 23 and outlet 24 can be reversed so that the outlet 24 is shared between the adjacent sections, and each of the sections has its own inlet. Stated differently, in some embodiments, adjacent sections share one of the inlet 23 and outlet 24 and have separate of the other of the inlet 23 and outlet 24.

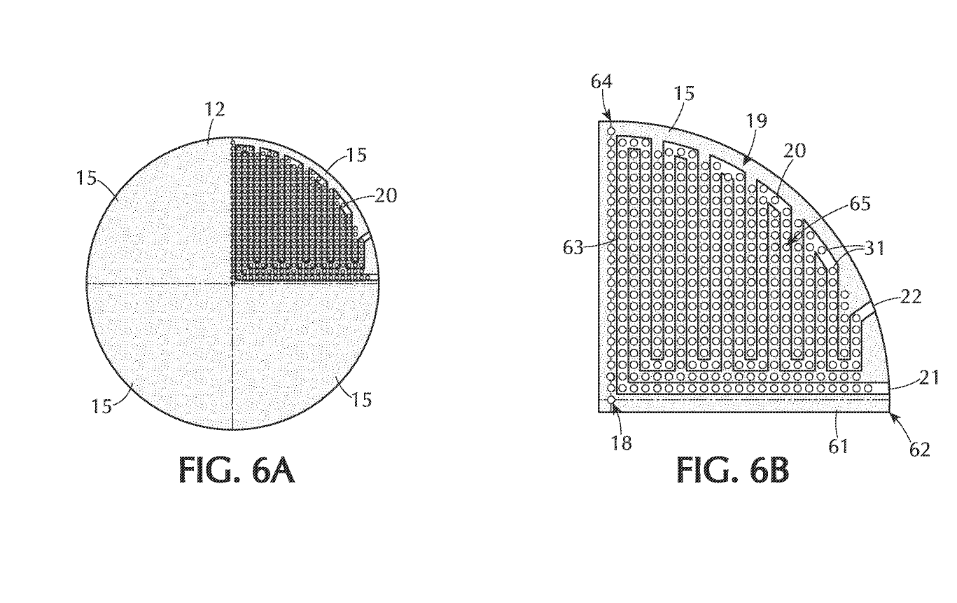

FIGS. 6A and 6B show another embodiment of a showerhead 11 divided into quarters. The difference between this embodiment and that of FIG. 3A is the shape of the flow channel 20. Here the flow channel in each section comprises a first leg 61 extending from a first corner 62 of the section 15 from the inlet end 21 toward the center 18 of the showerhead 11. The flow channel 20 turns to a second leg 63 toward a second corner 64. The first corner and the second corner are the opposite ends of the section 15 at the periphery or outer edge 19 of the showerhead 11. The flow channel 20 transitions into a series of switchback paths 65 which extend along a length of the second leg 63 between the first leg 61 and the outer edge 19 of the section to an outlet end 22. While the inlet end 21 and outlet end 22 are shown in specific locations, it will be understood that this is merely exemplary and that the inlet end 21 and outlet end 22 can be reversed. Stated differently, the first leg is connected to one of the inlet end 21 and outlet end 22 and the channel proceeds to the other of the inlet end 21 and outlet end 22.

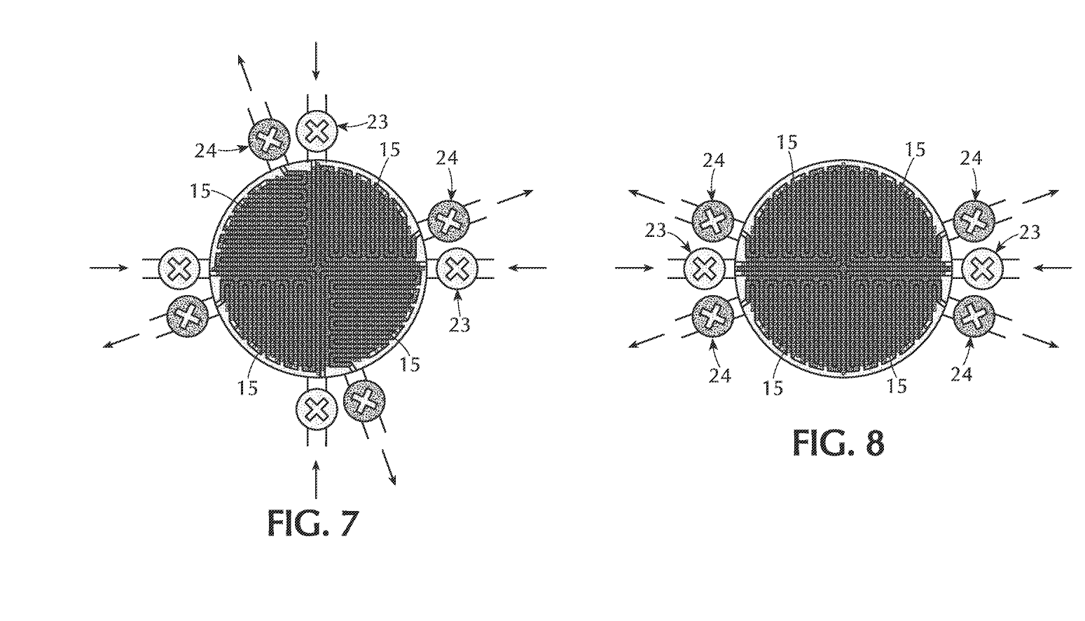

Again, the symmetry of the different sections 15 can be rotational, as shown in FIG. 7, or mirror-like, as shown in FIG. 8. It can also be seen from FIGS. 7 and 8 that the inlet 23 and outlet 24 can be separate for each section, or adjacent sections can share one of the inlet 23 and outlet 24.

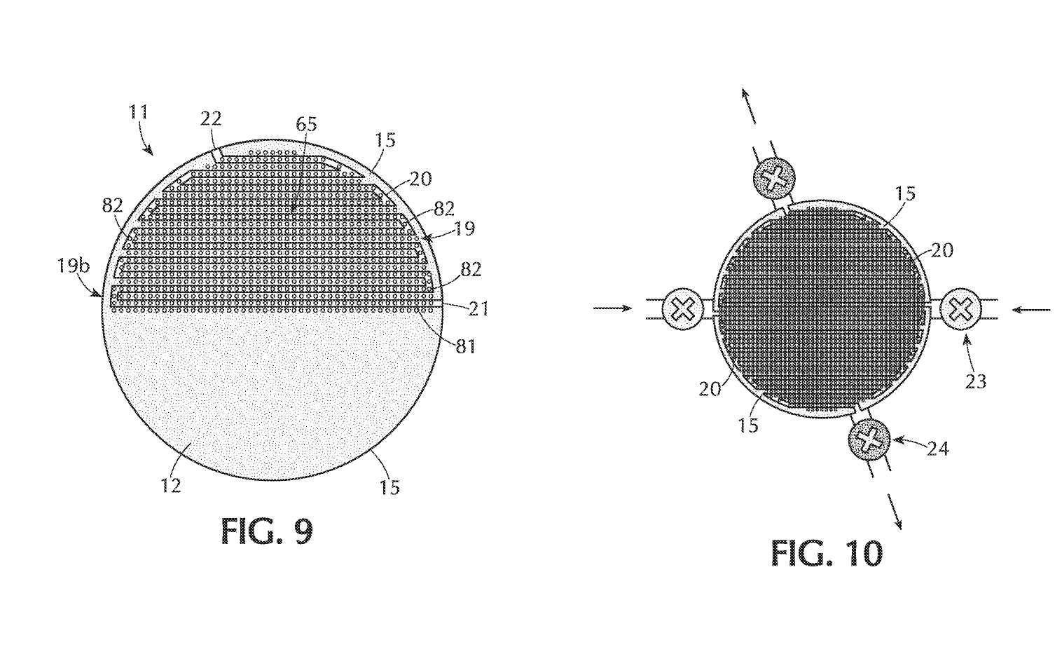

In the embodiment shown in FIG. 9, the showerhead 11 is divided into two equal sections 15. The sections 15 are shown as a top portion and a bottom portion, but this is merely for illustrative purposes. The flow channel 20 in each section 15 has a first leg 81 which extends from the inlet end 21 (or outlet end 22), at the inlet 23 (or outlet 24) from an edge 19 of the section 15 across the diameter (assuming a round showerhead 11) toward the opposite edge 19b. The flow channel 20 transitions to a series of switchback paths 65 which run extend along the length of the first leg 81 with increasing distance from the first leg 81 after each turn 82. FIG. 10 shows the showerhead 11 of FIG. 9 with rotational symmetry, but mirror symmetry is possible as well. Again, one of the inlet or outlet can be shared if adjacent (as in the mirror symmetry embodiments shown already).

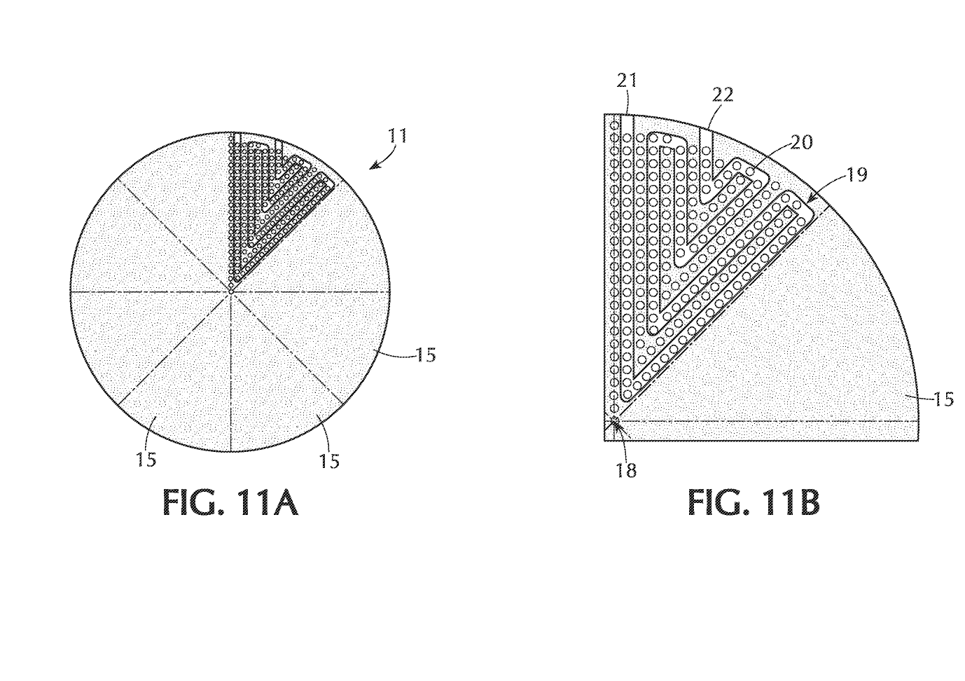

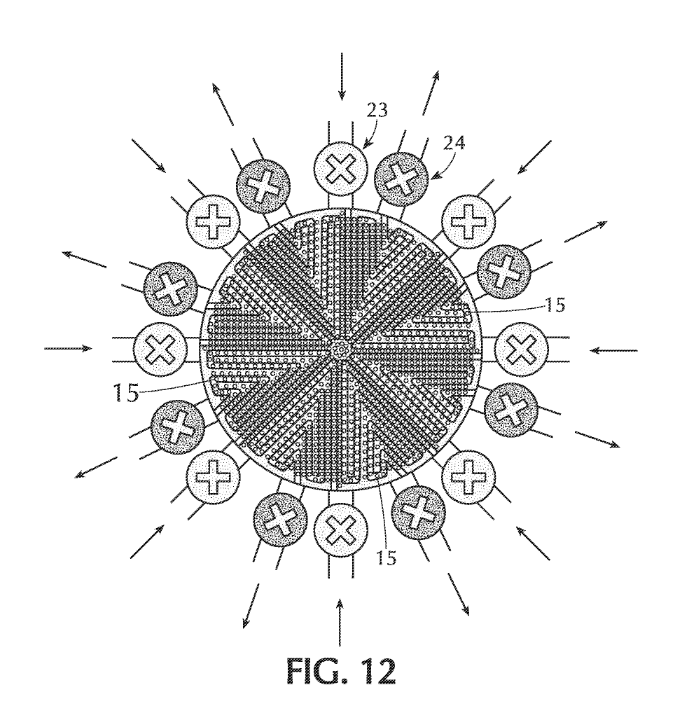

FIGS. 11A, 11B and 12 show another embodiment of the invention in which the showerhead 11 is divided into eight equal sections 15. The flow channel 20 follows along the edges of the section 15 and fills in the middle portion of the section 15 in a back and forth v-shaped path. FIG. 12 shows a rotationally symmetrical view of the showerhead 11 of FIGS. 11A and 11B, but a mirror symmetrical version is also possible and one of the inlet and outlet can be shared.

Each of the embodiments shown in FIGS. 1-12 have two lines of apertures 31 which follow along the same path. Each of these lines of aperture paths can be in flow communication with the same flow channel or a different flow channel. While the embodiments shown have the lines next to each other, it will be understood by those skilled in the art that the apertures can be in a single path with alternate apertures in flow communication with a different flow channel.

FIG. 13 shows an embodiment of a showerhead 11 with a first surface 12 and a second surface 14. The body 13 of the showerhead has suitable partitions to separate the showerhead into a lower flow channel 20a and an upper flow channel 20b. The upper flow channel 20b is in flow communication with a first gas and the lower flow channel 20a is in flow communication with a second gas, different from the first gas. A plurality of passages 30b connects the upper flow channel 20b to the first surface 12 at apertures 31b and a different plurality of passages 30a connects the lower flow channel 20b to the first surface 12 at apertures 31a.

The inlet 23b for the upper flow channel 20b is shown positioned in the middle of the showerhead 11 with outlets 24b on either end. A gas flowing through the inlet 23b would flow through the channel 20b, the passageway 30b and out of the apertures 31b into a processing region adjacent the showerhead 11. The position of the inlet and outlet can vary and should not be taken as limiting the scope of the invention. For example, the inlet and outlet can be in the same relative positions as those of the lower flow channel.

A gas flowing through the inlet 23a into the lower flow channel 20a would have a direct path to each of the passages 30a. The gas in the lower flow channel 20a could then pass through each of the passages 30a to the first surface 12 and into the processing region. The presence of the passages 30b connecting the upper flow channel to the first surface may or may not create a resistance to flow which may affect the uniformity of the gas flow.

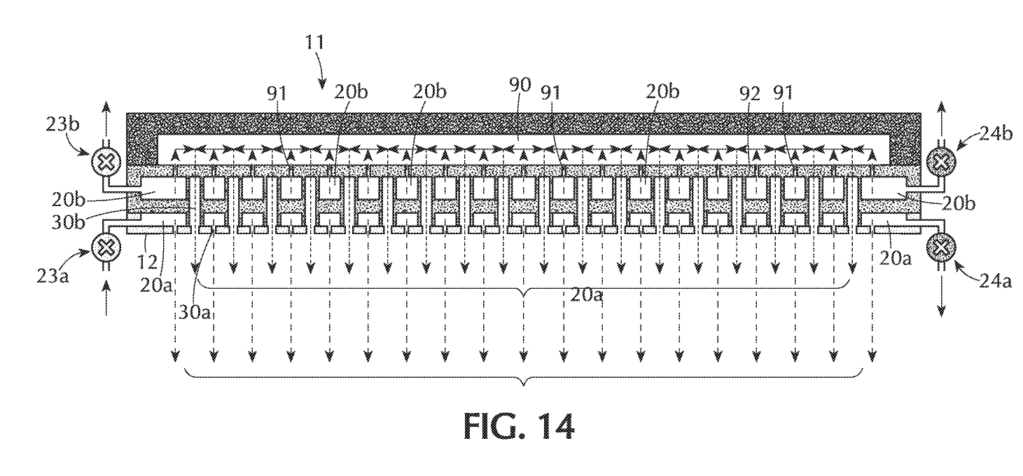

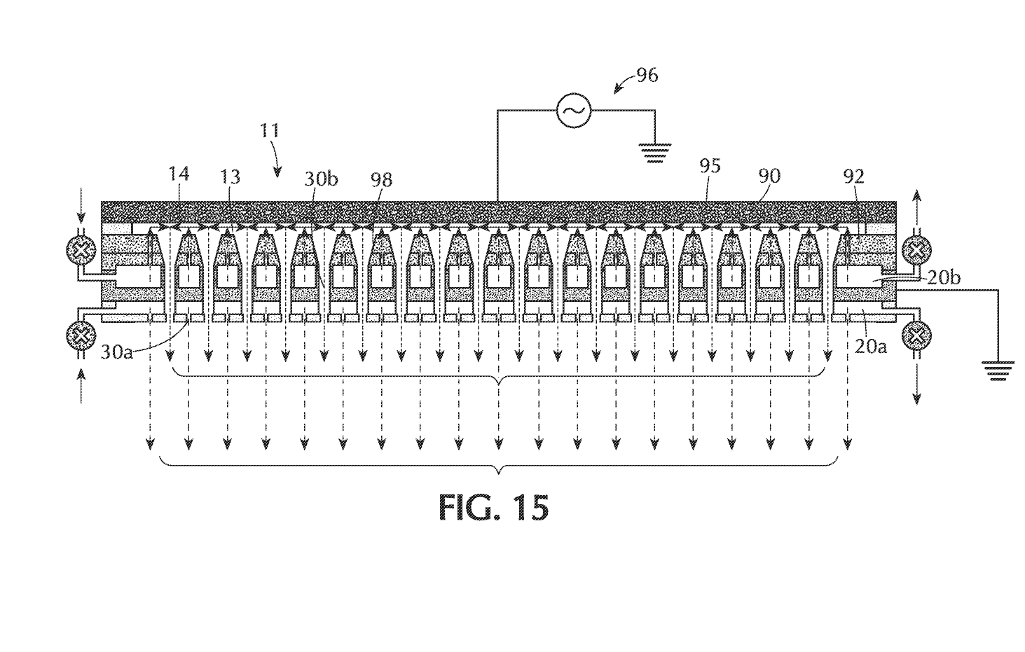

FIG. 14 shows an embodiment of the showerhead 11 which has a more uniform resistance between the upper flow channel 20b and the lower flow channel 20a. Here, the upper flow channel 20b includes a plenum 90 which forms a separate area in the flow channel. A gas flowing into the upper flow channel 20b will pass through openings 91 in a wall 92 to the plenum 90. The plurality of passages 30b connect the upper flow channel 20b to the first surface 12 of the showerhead 11 through the plenum 90. The presence of the wall 92 and openings 91 provide a similar resistance to flow as that experienced by the gas flowing through the lower flow channel 20a.

FIG. 15 shows another embodiment similar to FIG. 14 with the plenum 90. Here, the second surface 14 of the body 13 of the showerhead is an electrode 95. The electrode 95 can be connected to, for example, and RF power source 96 to create a plasma within the plenum 90 of the upper flow channel 20b. Any portion of the showerhead or processing chamber can serve as electrodes for the generation of the plasma. For example, the wall 92 can serve as an electrode. While the RF power source 96 is shown connected to a showerhead with two flow channels, it will be understood that the RF power source could be connected to a showerhead with a single flow channel as well.

FIG. 15 also shows an embodiment in which the passages 30b connecting the upper flow channel 20b to the first surface 12 have a funnel 98 shape. The funnel 98 has a wider opening in the plenum 90 than at the first surface 12.

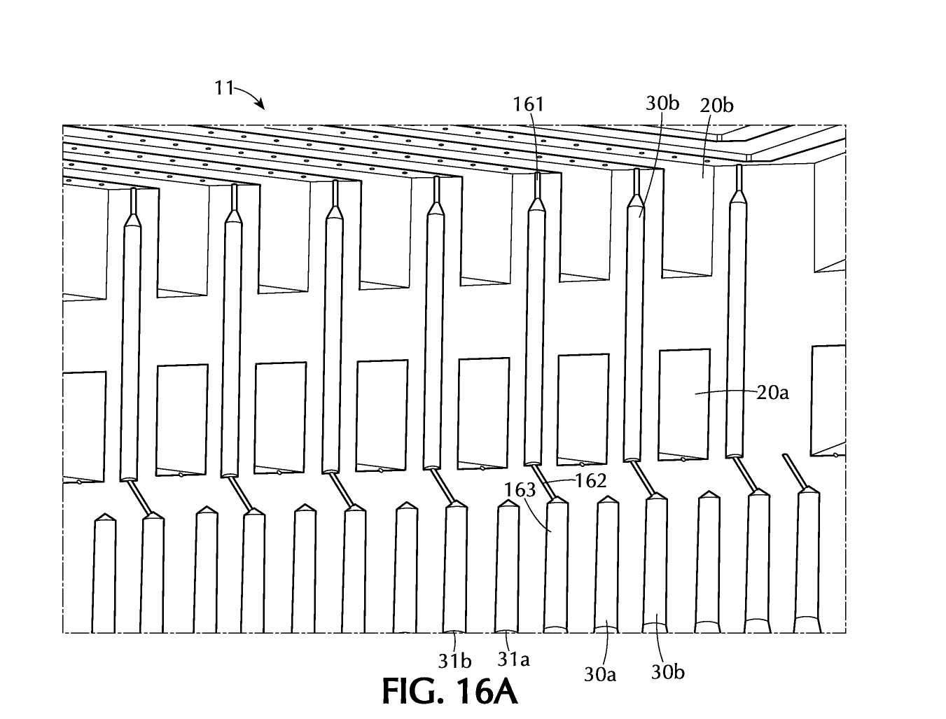

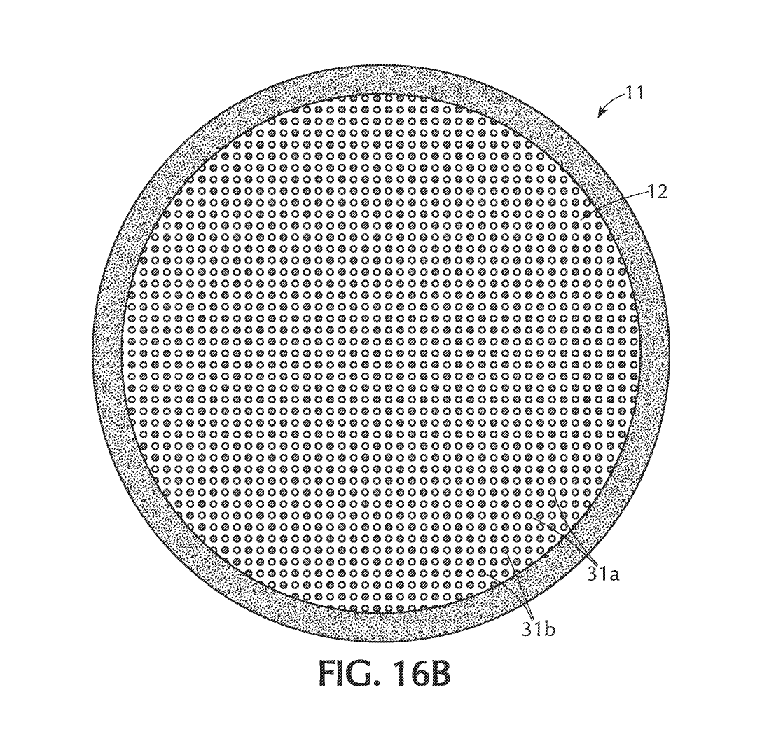

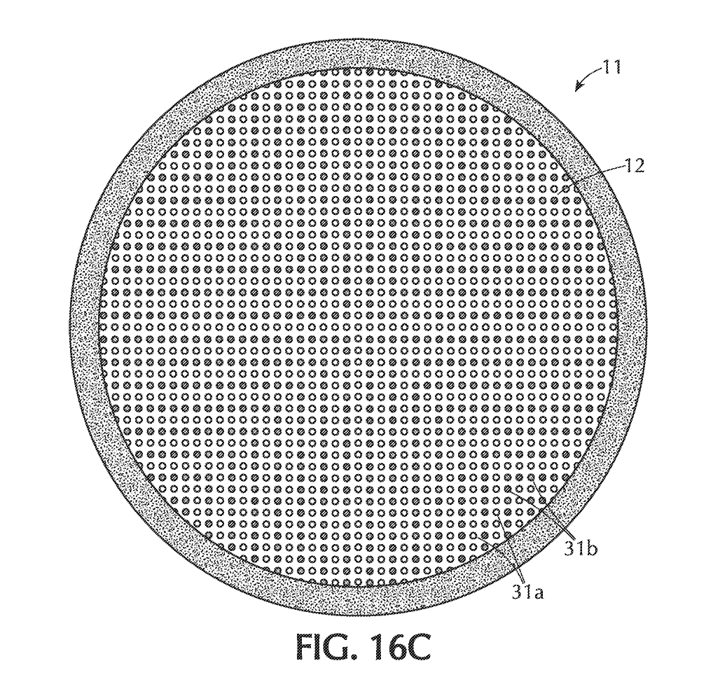

The angle of the passages 30 can be varied to change the flow pattern and uniformity. FIG. 16A shows a partial perspective view of a showerhead 11 in accordance with one or more embodiment of the invention. The showerhead 11 shown has a lower channel 20a and an upper channel 20b. A gas in the upper channel 20b flows into the passageway 30b and down toward the reaction region of the processing chamber. The passageway 30b can be straight, curved or angled. A flow of gas will pass from the upper channel 20b through an opening 161, shown as a shallow slit on the top surface of the channel wall, connecting the channel 20b to the passageway 30b. The gas flows down, past the lower channel 20a to an angled portion 162 where the gas flow shifts toward one side of the upper channel 20b and then out a lower straight portion 163 toward the substrate or reaction region of the processing chamber. Additionally, the gas flowing through the lower channel 20a is similarly shifted. The angled portion leading form the lower channel 20a to the passageway 30a is not shown because it is not in the same plane as the angled portion 162 of the upper passageway 30b. Such an arrangement allows the adjacent passageways to be offset from each other. In the embodiment shown in FIG. 16A, the adjacent passageways are offset by ½ pitch (meaning ½ the distance from the center of one channel to the center of the adjacent channel) from each other while keeping the flow of gas exiting the apertures 31a, 31b substantially perpendicular to the showerhead 11 first surface 12. FIG. 16B shows the hole pattern on the first surface 12 of a showerhead 11 in accordance with the embodiment of FIG. 16A. It can be seen that the hole pattern forms a uniform checkerboard pattern with alternating aperture 31a in communication with the lower channel 20a and aperture 31b in communication with the upper channel 20b. The shape of the channels 20a, 20b is not seen, or telegraphed, through to the first surface 12 of the showerhead 11. In contrast, FIG. 16C shows the first surface 12 of a showerhead 11 in accordance with the embodiment of FIG. 5 without the curved or angled passageways. In this case, each of the passageways extends from the channel 20a, 20b in the same direction as the adjacent passageways. The result being a first surface 12 which telegraphs the flow pattern of the channels.

The angle that the angled portion 162 of the passageway, relative to the first surface (i.e., 90° being perpendicular) can be any angle allowed by machining, for example, greater than about 15°, or greater than about 25°, or greater than about 35°, or greater than about 45°, or greater than about 55°, or greater than about 65°, or greater than about 75° or greater than about 85°. In some embodiment, the angle of the angled portion 162 is about 45°.

Embodiments of the invention generally relate to an apparatus and a method for depositing materials, and more particularly to a vapor deposition chamber configured to deposit a material during a plasma-enhanced process. In certain embodiments, a process chamber lid with a built-in plasma source for generating active reactant species adjacent to the process volume of a process chamber is provided. In certain embodiments, the process chamber lid assembly comprises multiple components that form a plasma cavity where the active reactant species are generated, with two separate pathways, each pathway for delivering each of a reaction gas or gases and a plasma to a process volume. The ability to generate plasma internally in the process lid assembly reduces the distance which the plasma activated species has to travel to reach the substrate surface in the process volume of a process chamber compared to systems using an RPS. The amount of available active species in the process volume is significantly increased and the required power to achieve the increase available active species is concurrently reduced.

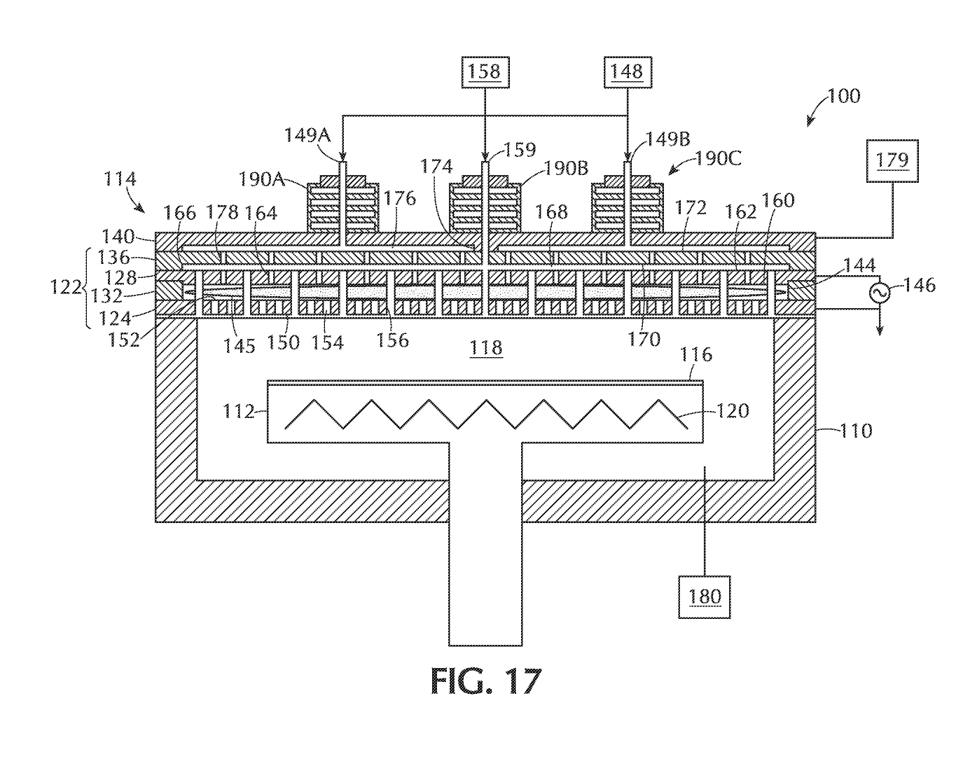

FIG. 17 is a schematic view of a process chamber 100 in accordance with one embodiment of the present invention. In one embodiment, the process chamber is adapted to form films with at least one plasma precursor. The process chamber 100 comprises a chamber body 110, a substrate support 112 disposed within the chamber body 110, and a process chamber lid assembly 114 disposed on the chamber body 110.

The substrate support 112 is configured to support one or more substrates 116 to expose the one or more substrates 116 to precursors in a process volume 118 defined by the chamber body 110 and the process lid assembly 114. In some embodiments, the substrate support 112 comprises a heater 120 that can (i.e., is adapted to) heat the one or more substrates 116 to a temperature required by the process being performed.

The process lid assembly 114 comprises a showerhead assembly 122 with a water box 140 for providing temperature control of the process lid assembly 114 positioned on the showerhead assembly 122. The showerhead assembly 122 comprises a first electrode 124 which also functions as a lid plate, a second electrode 128 which functions as a plasma cavity RF electrode positioned substantially parallel to the first electrode 124, an insulator 132 positioned in between the first electrode 124 and the second electrode 128, and a blocker plate 136 positioned on the second electrode 128. The first electrode 124, the insulator 132, and the second electrode 128 define a plasma cavity 144 where a capacitive plasma 145 can be generated. In one embodiment, the first electrode 124 is coupled to a RF (radio frequency) ground, the second electrode 128 is coupled to a RF power source 146, and the insulator 132 electrically insulates the first electrode 124 from the second electrode 128.

A first gas source 148 is coupled with the plasma cavity 144 via gas inlets 149A, 149B for providing one or more plasma forming gases to the plasma cavity 144. The capacitive plasma 145 can be generated in the plasma cavity 144 when an RF power is applied to the second electrode 128. Other gases such as carrier gases and purge gases may be coupled with the plasma cavity for delivering plasma forming gases to the plasma cavity and purging the process chamber 100 of plasma forming gases.

The first electrode 124 comprises a first surface 150 or lower surface adjacent to the process volume 118 and a second surface 152 or upper surface adjacent to the plasma cavity 144 with a plurality of first passages 154 formed therebetween. The plurality of first passages 154 couples the process volume 118 with the plasma cavity 144 and provides a conduit for delivering active reactant species from the plasma cavity 144 to the process volume 118. The plurality of first passages 154 may also be used to deliver other gases such as carrier gases, purge gases, and/or cleaning gases to the process chamber 100. In one embodiment, the plurality of first passages 154 are evenly distributed across a surface area of the first electrode 124 corresponding to a surface area of the substrate support 112. The first electrode 124 also has a plurality of second passages 156 coupling the process volume 118 with a second gas source 158 via gas inlet 159 for supplying one or more precursors to the process volume 118. The plurality of second passages 156 may also be used to deliver other gases such as carrier gases, purge gases, and/or cleaning gases to the process chamber 100.

In one embodiment, the first electrode 124 may be formed from a conductive material, such as metal or metal alloys. In one embodiment, the first electrode 124 is a planar disk. In one embodiment, the first electrode 124 is formed from a metal. Exemplary metals may be selected from the group consisting of aluminum, steel, stainless steel (e.g., iron-chromium alloys optionally containing nickel), iron, nickel, chromium, an alloy thereof, and combinations thereof.

The second electrode 128 comprises a first surface 160 or lower surface adjacent to the plasma cavity 144 and a second surface 162 or upper surface opposing the first surface with a plurality of third passages 164 formed between the first surface 160 and the second surface 162 for providing one or more plasma forming gases from the first gas source 148 to the plasma cavity 144. The plurality of third passages 164 may also be used to deliver other gases such as carrier gases, purge gases, and/or cleaning gases to the process chamber 100. As shown in FIG. 17, the plurality of second passages 156 traverse the plasma cavity 144 extending through the first surface 160 of the second electrode 128 to the second surface 162 of the second electrode 128.

In one embodiment, the second electrode 128 may be formed from a conductive material, such as metal or metal alloys. In one embodiment, the second electrode 128 is formed from a metal. Exemplary metals may be selected from the group consisting of aluminum, steel, stainless steel (e.g., iron-chromium alloys optionally containing nickel), iron, nickel, chromium, an alloy thereof, and combinations thereof. In one embodiment, the second electrode 128 is a planar disk.

The insulator 132 provides electrical insulation between the first electrode 124 and the second electrode 128 and may be formed from an electrically insulating material. In one embodiment, the insulator 132 is formed from a ceramic material, for example, aluminum nitride (AlₓN_{y}) or aluminum oxide (Al₂O₃).

The blocker plate 136 is disposed on the second electrode 128 and has a recessed portion 166 which forms a second gas region 168 defined by the recessed portion 166 and the second surface 162 of the second electrode 128. The second gas region 168 is positioned above and coupled with the process volume 118 via the plurality of second passages 156 for supplying the precursor gases to the process volume 118. The blocker plate 136 comprises a first surface 170 or lower surface and a second surface 172 or upper surface with the second gas region 168 defined between the first surface 170 of the blocker plate 136 and the second surface 162 of the second electrode 128. A plurality of fourth passages 178 for coupling the first surface 170 of the blocker plate 136 with the second surface 172 of the blocker plate 136 for coupling with the plurality of third passages 164 for delivering a plasma forming gas to the plasma cavity 144.

In one embodiment, one or more precursor gases from the second gas source 158 flows into the second gas region 168 via gas inlet 159 and through the plurality of second passages 156 and into the process volume 118 where they are delivered toward the surface of the one or more substrates 116. In one embodiment, the blocker plate 136 may comprise multiple plates which may be designed to aid in the uniform delivery of precursor gases to the process volume 118.

In one embodiment, the water box 140 is disposed on the blocker plate 136. The water box 140 may have a recessed portion 174 which forms a first gas region 176 defined by the recessed portion 174 and the second surface 172 of the blocker plate 136. The first gas region 176 is positioned above and coupled with the plasma cavity 144 via the plurality of third passages 164 for supplying the plasma forming gases to the plasma cavity. The plasma forming gas flows from the first gas source 148 to the first gas region 176 via gas inlets 149A, 149B where the plasma forming gas is distributed radially through the plurality of third passages 164 into the plasma cavity 144 where RF power is supplied to the second electrode 128 to form the capacitive plasma 145 in the plasma cavity 144. The activated radicals in the capacitive plasma 145 are then delivered to the process volume 118 via the plurality of first passages 154.

As shown in FIG. 17, the plurality of first passages 154 are offset (e.g., not having a “line of sight”) from the plurality of third passages 164 which aids in the uniform distribution of activated species to the wafer surface. As discussed herein, in certain embodiments, it is desirable for the plurality of first passages 154 to be lined up with or in the line of sight with the plurality of third passages 164. “Line-of-sight” as used herein refers to a straight path or a substantially straight path between two points. The straight path or the substantially straight path may provide an unobstructed pathway or an unobscured pathway for a gas or a plasma to flow between at least two points. Generally, an obstructed pathway or an obscured pathway prohibits or substantially reduces the passage of a plasma while permitting the passage of a gas. Therefore, a line-of-sight pathway usually permits the passage of a gas or a plasma, while a pathway not having a line of sight between two points prohibits or substantially reduces the passage of a plasma and permits the passage of a gas.

The water box 140 is used to regulate the temperature of the process chamber 100 by removing heat from the process lid assembly, such as the process lid assembly 114. The water box 140 may be positioned on top of the showerhead assembly 122. The water box 140 removes heat from the process lid assembly 114, such as from showerhead assembly 122. During a deposition process, a fluid at an initial temperature is administered into the water box 140 through an inlet (not shown). The fluid absorbs heat while traveling along a passageway (not shown). The fluid at a higher temperature is removed from the water box 140 via an outlet (not shown). The water box 140 may contain or be formed from a metal such as aluminum, aluminum alloys (e.g., aluminum magnesium silicon alloys, such as aluminum 6061), aluminum-plated metals, stainless steel, nickel, nickel alloys, nickel-plated aluminum, nickel-plated metal, chromium, iron, alloys thereof, derivatives thereof, or combinations thereof. In one example, the water box 140 may contain or is formed from aluminum or an aluminum alloy.

The water box 140 may be connected to a fluid source 179 for supplying fluid to the water box 140 during the deposition process. The fluid may be in liquid, gas or supercritical state and is capable of adsorbing and dissipating heat in a timely manner. Liquids that may be used in the water box 140 include water, oil, alcohols, glycols, glycol ethers, other organic solvents, supercritical fluids (e.g., CO₂) derivatives thereof or mixtures thereof. Gases may include nitrogen, argon, air, hydrofluorocarbons (HFCs), or combinations thereof. Preferably, the water box 140 is supplied with water or a water/alcohol mixture.

The process chamber 100 further comprises a vacuum pump 180 configured to pump out the process volume 118 to obtain a desired pressure level in the process volume 118. During processing, the vacuum pump 180 provides a negative pressure in the process volume 118 relative to the plasma cavity 144, thus allowing the species in the plasma cavity 144 to flow to the process volume 118.

In certain embodiments, ferrite containing elements 190A, 190B, and 190C are positioned adjacent to at least one of the gas inlets 149A, 149B and 159. The ferrite containing elements 190A, 190B, and 190C may be positioned adjacent to the gas inlets 149A, 149B and 159 to reduce the formation of parasitic plasma or arcing near the gas inlets 149A, 149B and 159. The ferrite containing elements 190A, 190B, and 190C may form parallel ferrite boundaries that suppress RF currents perpendicular to the ferrite boundary and absorb magnetic field components parallel to the boundary.

The ferrite containing elements 190A, 190B, 190C may be formed from any material that can be used to provide a path through which the generated fields (e.g., magnetic fields), created by the flow of RF current within portions of the process chamber 100, will preferentially flow. In one example, the ferrite containing elements 190A, 190B, and 190C may be formed from or embedded with a ferrite material. Ferrite materials may include non-conductive ferromagnetic ceramic compounds derived from iron oxides such as hematite (Fe₂O₃) or magnetite (Fe₃O₄) as well as oxides of other metals. Ferrite materials may further contain nickel, zinc, and/or manganese compounds. Exemplary ferrite materials include manganese ferrites, manganese zinc ferrites, nickel zinc ferrites, and combinations thereof.

The ferrite containing elements 190A, 190B, and 190C may take the form of any shape that suppresses RF currents perpendicular to the ferrite boundary and absorb magnetic field components parallel to the boundary. Exemplary shapes for the ferrite containing elements 190A, 190B, and 190C include rings, toroids, and coils. In one exemplary embodiment, the gas inlet 149B is an aluminum tube and the ferrite containing element 190B contains a plurality of toroid or donut-shaped ferrite members containing nickel-zinc ferrites. In another exemplary embodiment, as shown in FIG. 17, the gas inlets 149A, 149B, and 159 are aluminum tubes, each aluminum tube surrounded by a respective ferrite containing element 190A, 190B, and 190C containing a plurality of toroid or donut-shaped ferrite members that contain nickel-zinc ferrites.

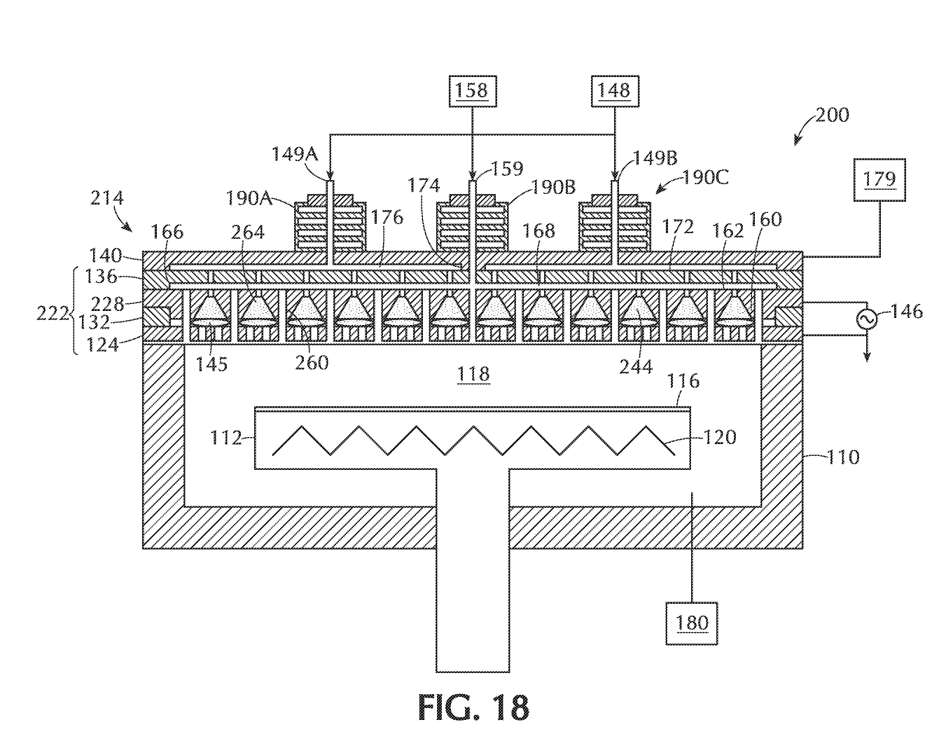

FIG. 18 is a schematic view of another process chamber 200 having another embodiment of a process lid assembly 214 in accordance with one embodiment of the present invention. The process chamber 200 is similar to process chamber 100 shown in FIG. 17 except that the second electrode 128 of process chamber 100 is replaced with second electrode 228 which has a plurality of multiple cone-shaped cavities 264. The cone-shaped cavities in combination with the variable distance between the first electrode 124 and the second electrode 228 allows for a wider plasma ignition window. Plasma can be effectively initiated in the cone-shaped cavities 264 and as a result, uniform plasma can be maintained across the entire plasma cavity in between the first electrode 124 and the second electrode 228.

The process lid assembly 214 comprises a showerhead assembly 222 with a water box 140 positioned on the showerhead assembly 222. The showerhead assembly 222 comprises the first electrode 124, a second electrode 228 positioned substantially parallel to the first electrode 124, the insulator 132 positioned in between the first electrode 124 and the second electrode 228, and the blocker plate 136 positioned on the second electrode 228. The first electrode 124, the insulator 132, and the second electrode 228 define a plasma cavity 244 where capacitive plasma may be generated. In one embodiment, the first electrode 124 is coupled to a RF (radio frequency) ground, the second electrode 228 is coupled to a RF power source 146, and the insulator 132 electrically insulates the first electrode 124 from the second electrode 228.

FIG. 19 is a partial sectional view of the second electrode 228 for the process lid assembly 214 in accordance with one embodiment of the present invention. The second electrode 228 comprises a first surface 260 or lower surface for positioning adjacent to the plasma cavity 244 and a second surface 262 or upper surface opposing the first surface 260 with a plurality of second passages 256 for supplying one or more precursors to a process volume and a plurality of third passages 264 formed therebetween for providing one or more reactive gases a gas source to the plasma cavity 244.

In one embodiment, the plurality of third passages 264 may be evenly distributed over the second electrode 228. In one embodiment, the plurality of third passages 264 comprises a narrow bore 270 coupled to a cone-shaped channel 272 having a diameter that expands as the plurality of third passages 264 extend from the second surface 262 of the second electrode 228 to the first surface 260 of the second electrode 228. In one embodiment, the sidewalls of the cone-shaped channel 272 form an angle. In one embodiment, the angle is between about 20° and about 30°.

In one embodiment, the plurality of second passages 256 may be evenly distributed over the second electrode 228. In one embodiment, the plurality of second passages 256 comprises a narrow bore 258 extending from the first surface 260 coupled to a straight channel 259 that extends to the second surface 262 of the second electrode 228.

In one embodiment, the second electrode 228 may be formed from a conductive material, such as metal or metal alloys. In one embodiment, the second electrode 228 is formed from a metal. Exemplary metals may be selected from the group consisting of aluminum, steel, stainless steel (e.g., iron-chromium alloys optionally containing nickel), iron, nickel, chromium, an alloy thereof, and combinations thereof. In one embodiment, the second electrode 228 is a planar disk.

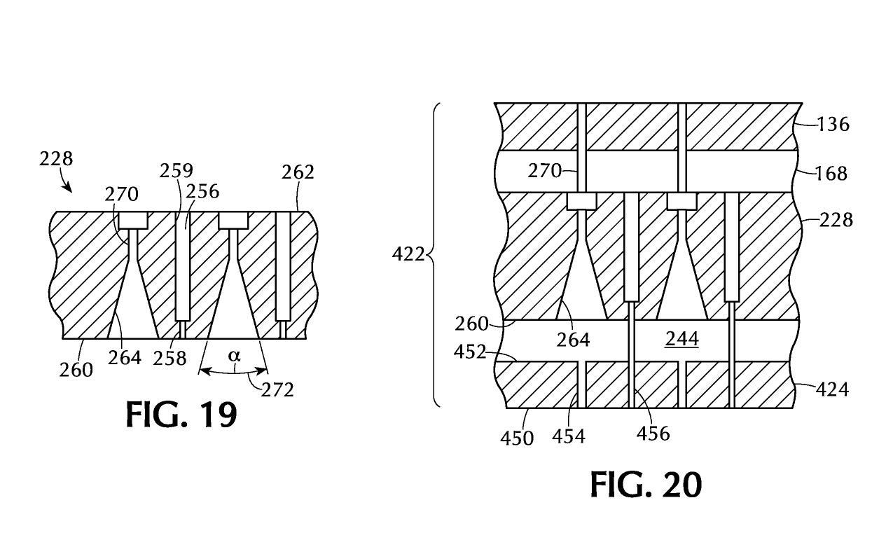

FIG. 20 is a partial sectional view of a showerhead assembly 422 for a process lid assembly in accordance with one embodiment of the present invention. The showerhead assembly 422 is similar to showerhead assembly 222 except that the first electrode 424 has a plurality of first passages 454 that are aligned with or in the “line of sight” of the plurality of third passages 264 for delivering activated species to a process volume of a process chamber, such as process chambers 100, 200. In certain embodiments where the plurality of first passages 454 is aligned with the plurality of third passages 264 a higher volume of reactive species may be delivered to the process volume using lower power levels.

The first electrode 424 comprises a first surface 450 or lower surface adjacent to a process volume 118 and a second surface 452 or upper surface adjacent to the plasma cavity 244 with a plurality of first passages 454 formed therebetween. The plurality of first passages 454 couple the process volume 118 with the plasma cavity 244 and provide a conduit for delivering active reactant species from the plasma cavity 244 to the process volume 118. The plurality of first passages 454 may also be used to deliver other gases such as carrier gases, purge gases, and/or cleaning gases to the process chamber 100. In one embodiment, the plurality of first passages 454 are evenly distributed across a surface area of the first electrode 424 corresponding to a surface area of the substrate support 112. The first electrode 424 also has a plurality of second passages 456 coupling the process volume 118 with a second gas source for supplying one or more precursors to the process volume 118. The plurality of second passages 456 may also be used to deliver other gases such as carrier gases, purge gases, and/or cleaning gases to the process chamber 100.

In one embodiment, the first electrode 424 may be formed from a conductive material, such as metal or metal alloys. In one embodiment, the first electrode 424 is a planar disk. In one embodiment, the first electrode 424 is formed from a metal, such as aluminum, steel, stainless steel (e.g., iron-chromium alloys optionally containing nickel), iron, nickel, chromium, an alloy thereof or combinations thereof.

Each component (e.g., the first electrodes 124, 424, the insulator 132, the second electrodes 128, 228, the blocker plates 136, the water box 140, and the gas distribution assembly) may be scaled to process a substrate of varying size, such as a wafer with a 150 mm diameter, a 200 mm diameter, a 300 mm diameter, or larger. Each component may be positioned and secured on the first electrodes 124, 424 or lid plate by any securing means known in the art such as, for example, clips and/or fasteners.

Embodiments described herein provide methods for depositing a variety of material (e.g., titanium nitride) on a substrate by a vapor deposition process, such as atomic layer deposition (ALD) or plasma-enhanced ALD (PE-ALD). In one aspect, the process has little or no initiation delay and maintains a fast deposition rate while forming a titanium material, such as metallic titanium, titanium nitride, titanium silicon nitride, or derivatives thereof.

In one embodiment, titanium precursors that may be used with the PE-ALD processes described herein include tetrakis(dimethylamino)titanium (TDMAT), tetrakis(diethylamino)titanium (TDEAT), titanium tetrachloride (TiCl₄), and derivatives thereof. The PE-ALD processes described herein include sequentially exposing a substrate with a nitrogen precursor and a nitrogen plasma or other ionized reagent plasma.

Operation of the processing chamber is described herein with respect to the formation of a titanium nitride film. However, it will be understood by those skilled in the art that this is merely one possible film and should not be taken as limiting the scope of the invention and that can be formed and that other films are within the scope of the invention. The processing conditions described with respect to the titanium nitride film deposition may be applicable to other films as well.

In one embodiment, a titanium nitride material may be formed during a PE-ALD process containing a constant flow of a reagent gas while providing sequential pulses of a titanium precursor and a plasma. In another embodiment, a titanium material may be formed during another PE-ALD process that provides sequential pulses of a titanium precursor (e.g., TDMAT) and a reagent plasma (e.g., nitrogen plasma). In both of these embodiments, the reagent is generally ionized during the process. The PE-ALD process provides that the plasma is generated internally in the showerhead assembly thus reducing the distance which the plasma activated species has to travel to reach the substrate surface is dramatically reduced compared to systems using an RPS. The amount of available active species in the process volume is significantly increased and the required power to achieve an increase in available active species is concurrently reduced. During PE-ALD processes, a plasma may be generated from a microwave (MW) frequency generator, a radio frequency (RF) generator, or pulsed DC current. In another embodiment, a titanium material may be formed during a thermal ALD process that provides sequential pulses of a titanium precursor and a reagent. Both the process gas containing TDMAT and the nitrogen plasma are sequentially pulsed to and through showerhead assembly 122, 222. Thereafter, the substrate is sequentially exposed to the process gas and the nitrogen plasma.

In some embodiments, the deposition chamber may be pressurized at a pressure within a range from about 0.01 Torr to about 80 Torr, preferably from about 0.1 Torr to about 10 Torr, and more preferably, from about 0.5 Torr to about 2 Torr during the ALD processes described herein. Also, the chamber or the substrate may be heated to a temperature of less than about 500° C., preferably, about 400° C. or less, such as within a range from about 200° C. to about 400° C., and more preferably, from about 340° C. to about 370° C., for example, about 360° C. during several of the ALD processes described herein. The plasma may be generated by a microwave (MW) generator or a radio frequency (RF) generator. For example, the plasma generator may be set to have a power output within a range from about 200 watts (W) to about 40 kilowatts (kW), preferably, from about 200 kW to about 10 kW, and more preferably, from about 500 W to about 3 kW.

In one embodiment, the substrate may be exposed to a reagent gas throughout the whole ALD cycle. The substrate may be exposed to a titanium precursor gas supplied from the second gas source 158 by passing a carrier gas (e.g., nitrogen or argon) through an ampoule of a titanium precursor. The ampoule may be heated depending on the titanium precursor used during the process. In one example, an ampoule containing TDMAT may be heated to a temperature within a range from about 25° C. to about 80° C. The titanium precursor gas usually has a flow rate within a range from about 100 sccm to about 2,000 sccm, preferably, from about 200 sccm to about 1,000 sccm, and more preferably, from about 300 sccm to about 700 sccm, for example, about 500 sccm. The titanium precursor gas and the reagent gas may be combined to form a deposition gas. A reagent gas usually has a flow rate within a range from about 100 sccm to about 3,000 sccm, preferably, from about 200 sccm to about 2,000 sccm, and more preferably, from about 500 sccm to about 1,500 sccm. In one example, nitrogen plasma is used as a reagent gas with a flow rate of about 1,500 sccm. The substrate may be exposed to the titanium precursor gas or the deposition gas containing the titanium precursor and the reagent gas for a time period within a range from about 0.1 seconds to about 8 seconds, preferably, from about 1 second to about 5 seconds, and more preferably, from about 2 seconds to about 4 seconds. The flow of the titanium precursor gas may be stopped once a layer of the titanium precursor is adsorbed on the substrate. The layer of the titanium precursor may be a discontinuous layer, a continuous layer, or even multiple layers.

The substrate and chamber may be exposed to a purge process after stopping the flow of the titanium precursor gas. The flow rate of the reagent gas may be maintained or adjusted from the previous step during the purge process. Preferably, the flow of the reagent gas is maintained from the previous step. Optionally, a purge gas may be administered into the deposition chamber with a flow rate within a range from about 100 sccm to about 2,000 sccm, preferably, from about 200 sccm to about 1,000 sccm, and more preferably, from about 300 sccm to about 700 sccm, for example, about 500 sccm. The purge process removes any excess titanium precursor and other contaminants within the deposition chamber. The purge process may be conducted for a time period within a range from about 0.1 seconds to about 8 Seconds, preferably, from about 1 second to about 5 seconds, and more preferably, from about 2 seconds to about 4 seconds. The carrier gas, the purge gas and the process gas may contain nitrogen, hydrogen, ammonia, argon, neon, helium or combinations thereof. In a preferred embodiment, the carrier gas contains nitrogen.

Thereafter, the flow of the reagent gas may be maintained or adjusted before igniting a plasma. During processing, a nitrogen source, such as nitrogen gas, is supplied from the first gas source 148. The nitrogen gas flows into the plasma cavity 144, where the nitrogen gas is dissociated when a plasma of the nitrogen gas is ignited by the RF power applied between the first electrode 124 and the second electrode 128. The free nitrogen radicals (nitrogen atoms) then flow through the plurality of first passages 154 into the process volume 118.

The substrate may be exposed to the plasma for a time period within a range from about 0.1 seconds to about 20 seconds, preferably, from about 1 second to about 10 seconds, and more preferably, from about 2 seconds to about 8 seconds. Thereafter, the plasma power was turned off. In one example, the reagent may be ammonia, nitrogen, hydrogen or a combination thereof to form an ammonia plasma, a nitrogen plasma, a hydrogen plasma, or a combined plasma. The reactant plasma reacts with the adsorbed titanium precursor on the substrate to form a titanium material thereon. In one example, the reactant plasma is used as a reducing agent to form metallic titanium. However, a variety of reactants may be used to form titanium materials having a wide range of compositions.

The deposition chamber was exposed to a second purge process to remove excess precursors or contaminants from the previous step. The flow rate of the reagent gas may be maintained or adjusted from the previous step during the purge process. An optional purge gas may be administered into the deposition chamber with a flow rate within a range from about 100 sccm to about 2,000 sccm, preferably, from about 200 sccm to about 1,000 sccm, and more preferably, from about 300 sccm to about 700 sccm, for example, about 500 sccm. The second purge process may be conducted for a time period within a range from about 0.1 seconds to about 8 seconds, preferably, from about 1 second to about 5 seconds, and more preferably, from about 2 seconds to about 4 seconds.

The ALD cycle may be repeated until a predetermined thickness of the titanium material is deposited on the substrate. The titanium material may be deposited with a thickness less than 1,000 Å, preferably less than 500 Å and more preferably from about 10 Å to about 100 Å, for example, about 30 Å. The processes as described herein may deposit a titanium material at a rate of at least 0.15 Å/cycle, preferably, at least 0.25 Å/cycle, more preferably, at least 0.35 Å/cycle or faster. In another embodiment, the processes as described herein overcome shortcomings of the prior art relative as related to nucleation delay. There is no detectable nucleation delay during many, if not most, of the experiments to deposit the titanium materials.

Even though metal nitride film formation is discussed with the embodiments described herein, it should be understood that other processes requiring radicals can also be performed using the apparatus and methods described herein.

Embodiments described herein provide the ability to generate plasma internally in the process lid assembly which reduces the distance which the plasma activated species has to travel to reach the substrate surface in the process volume of a process chamber compared to systems using an RPS. The amount of available active species in the process volume is significantly increased and the required power to achieve the increase available active species is concurrently reduced.

Substrates for use with the embodiments of the invention can be any suitable substrate. In detailed embodiments, the substrate is a rigid, discrete, generally planar substrate. As used in this specification and the appended claims, the term “discrete” when referring to a substrate means that the substrate has a fixed dimension. The substrate of specific embodiments is a semiconductor wafer, such as a 200 mm or 300 mm diameter silicon wafer.

As used in this specification and the appended claims, the terms “reactive gas”, “reactive precursor”, “first precursor”, “second precursor” and the like, refer to gases and gaseous species capable of reacting with a substrate surface or a layer on the substrate surface.

As used in this specification and the appended claims, the term “exited gaseous species” means any gaseous species not in the ground electronic state. For example, molecular oxygen may be excited to form oxygen radicals, with the oxygen radicals being the excited species. Additionally, the terms “excited species”, “radical species,” and the like, are intended to mean a species not in the ground state. As used in this specification and the appended claims, the term “substrate surface” means the bare surface of the substrate or a layer (e.g., an oxide layer) on the bare substrate surface.

In some embodiments, one or more layers may be formed during a plasma enhanced atomic layer deposition (PEALD) process. In some processes, the use of plasma provides sufficient energy to promote a species into the excited state where surface reactions become favorable and likely. Introducing the plasma into the process can be continuous or pulsed. In some embodiments, sequential pulses of precursors (or reactive gases) and plasma are used to process a layer. In some embodiments, the reagents may be ionized either locally (i.e., within the processing area) or remotely (i.e., outside the processing area). In some embodiments, remote ionization can occur upstream of the deposition chamber such that ions or other energetic or light emitting species are not in direct contact with the depositing film. In some PEALD processes, the plasma is generated external from the processing chamber, such as by a remote plasma generator system. The plasma may be generated via any suitable plasma generation process or technique known to those skilled in the art. For example, plasma may be generated by one or more of a microwave (MW) frequency generator or a radio frequency (RF) generator. The frequency of the plasma may be tuned depending on the specific reactive species being used. Suitable frequencies include, but are not limited to, 2 MHz, 13.56 MHz, 40 MHz, 60 MHz and 100 MHz. Although plasmas may be used during the deposition processes disclosed herein, it should be noted that plasmas may not be required. Indeed, other embodiments relate to deposition processes under very mild conditions without a plasma.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the desired separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. The details of one such staged-vacuum substrate processing apparatus is disclosed in U.S. Pat. No. 5,186,718, entitled “Staged-Vacuum Wafer Processing Apparatus and Method,” Tepman et al., issued on Feb. 16, 1993. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the silicon layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, like a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposure to different reactive or purge gases. Rotating the substrate during processing (either continuously or in steps) may help produce a more uniform deposition or etch by minimizing the effect of, for example, local variability in gas flow geometries.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A gas distribution assembly comprising:
a showerhead comprising a body with a first surface and a second surface, the showerhead divided into a plurality of sections;
each of the plurality of sections comprising a flow channel extending through the body of the showerhead, the flow channel including an inlet end and an outlet end, the inlet end in fluid communication with an inlet and the outlet end in fluid communication with an outlet; and
a plurality of passages extending from the flow channel through the body to the first surface to form an aperture on the first surface so that a gas in the flow channel can flow through the passages and out of the apertures on the first surface.

2. The gas distribution assembly of claim 1, wherein each section is about one-quarter of the showerhead.

3. The gas distribution assembly of claim 2, wherein the flow channel in each section comprises a series of connected L-shaped portions decreasing in size from a center of the showerhead toward an outer portion of the showerhead.

4. The gas distribution assembly of claim 3, wherein the flow channels in each section are rotationally symmetrical to the other flow channels and each flow channel is in flow communication with a separate inlet and outlet.

5. The gas distribution assembly of claim 3, wherein the flow channel in each section are mirror images of the adjacent sections and two adjacent sections share one of the inlet and outlet and have separate of the other of the inlet and outlet.

6. The gas distribution assembly of claim 2, wherein the flow channel in each section comprises a first leg extending from a first corner of the section from one of the inlet and outlet toward a center of the showerhead where the flow channel turns to a second leg extending from the center toward a second corner of the section and transitioning to a series of switchback paths extending along a length of the second leg between the first leg and an edge of the section to the other of the inlet and outlet.

7. The gas distribution assembly of claim 6, wherein the flow channels in each section are rotationally symmetrical to the other flow channels and each flow channel is in fluid communication with a separate inlet and outlet.

8. The gas distribution assembly of claim 6, wherein the flow channel in each section is a mirror image of the adjacent sections and two adjacent section share on of the inlet and out and a separate of the other of the inlet and outlet.

9. The gas distribution assembly of claim 1, wherein the showerhead is divided into two equal sections.

10. The gas distribution assembly of claim 9, wherein the flow channel in each section comprises a first leg extending from an edge of the section across the diameter of the showerhead toward about the opposite edge of the section transitioning to a series of switchback paths extending along the length of the first leg with increasing distance from the first leg.

11. The gas distribution assembly of claim 1, wherein the showerhead is divided into eight equal sections.

12. The gas distribution assembly of claim 1, further comprising an electrode to be coupled with an RF power source to generate a plasma in the flow channel.

13. The gas distribution assembly of claim 1, wherein each of the plurality of sections comprises an upper flow channel and a lower flow channel, the upper flow channel in flow communication with a first gas and the lower flow channel in flow communication with a second gas different from the first gas, a plurality of passages connects the upper flow channel to the first surface and a plurality of passages connects the lower flow channel to the first surface.

14. The gas distribution assembly of claim 13, wherein the upper flow channel comprises a wall and a plenum above the inlet, the wall including a plurality of openings to allow a gas to flow from the inlet into the plenum and the plurality of passages connecting the upper flow channel to the first surface are in fluid communication with the plenum.

15. The gas distribution assembly of claim 14, wherein the upper flow channel further comprises an electrode connected to an RF power source to generate a plasma in the plenum.

16. The gas distribution assembly of claim 14, wherein the plurality of passages connecting the upper flow channel to the first surface are funnel shaped with a wider opening in the plenum than at the first surface.

17. The gas distribution assembly of claim 13, wherein each of the plurality of passages independently includes an angled portion in a middle of the passageway to offset of the passageway to direct a flow of gas perpendicular to the first surface so that from the first surface, the plurality of passageways form a checkerboard pattern with alternate passageways in communication with different channels.

18. A chamber for plasma enhanced processing of one or more substrates, the chamber comprising:
a chamber body defining a process volume;
a substrate support disposed in the process volume to support one or more substrates;
a showerhead comprising a body with a first surface and a second surface, the showerhead divided into a plurality of sections, each of the plurality of sections comprising a flow channel extending through the body of the showerhead, the flow channel including an inlet end and an outlet end, the inlet end in fluid communication with an inlet and the outlet end in fluid communication with an outlet and a plurality of passages extending from the flow channel through the body to the first surface to form an aperture on the first surface so that a gas in the flow channel can flow through the passages and out of the apertures on the first surface;
a plasma forming gas source coupled with the showerhead; and
a reactant gas source coupled with the showerhead.

19. The chamber of claim 18, wherein each of the plurality of sections comprises an upper flow channel and a lower flow channel, the upper flow channel in flow communication with a first gas and the lower flow channel in flow communication with a second gas different from the first gas, a plurality of passages connects the upper flow channel to the first surface and a plurality of passages connects the lower flow channel to the first surface.

20. A gas distribution assembly comprising:
a showerhead comprising a body with a first surface and a second surface, the showerhead divided into a plurality of sections;
each of the plurality of sections comprising an upper flow channel extending through the body of the showerhead and a lower flow channel extending through the body of the showerhead, each flow channel including an inlet end and an outlet end, the inlet end in fluid communication with an inlet and the outlet end in fluid communication with an outlet;
a plurality of passages extending from the upper flow channel through the body to the first surface to form an aperture on the first surface so that a gas in the upper flow channel can flow through the passages and out of the apertures on the first surface, wherein at least some of the passageways include an angled portion to offset the flow of gas through the passageway; and
a plurality of passages extending from the lower flow channel through the body to the first surface to form an aperture on the first surface so that a gas in the lower flow channel can flow through the passages and out of the apertures on the first surface, wherein at least some of the passageways include an angled portion to offset the flow of gas through the passageway.
